(19) United States
(12) Patent Application Publication
(10) Pub. No.: US 2013/0075798 A1
(43) Pub. Date: Mar. 28, 2013

(54) SEMICONDUCTOR DEVICE

(71) Applicant: Kazuhiro KATO, Yokohama-shi (JP)

(72) Inventor: Kazuhiro KATO, Yokohama-shi (JP)

(73) Assignee: Kabushiki Kaisha Toshiba, Tokyo (JP)

(21) Appl. No.: 13/418,224

(22) Filed: Mar. 12, 2012

(30) Foreign Application Priority Data
Sep. 22, 2011 (JP) P2011-207266

(51) Int. Cl. H01L 27/06

(52) U.S. Cl. 257/296; 257/E27.016

(57) ABSTRACT

A semiconductor device comprises: a MOS transistor connected between a power supply terminal and a ground terminal; a first diode connected between a drain and a gate of the MOS transistor; a second diode connected between the drain and the gate of the MOS transistor, in series with the first diode, and having a forward direction which is opposite to that of the first diode; and a capacitor connected between the drain and the gate of the MOS transistor, in series with the first diode and the second diode.

### CROSS-REFERENCE TO RELATED APPLICATIONS

This application is based upon and claims the benefit of priority from the prior Japanese Patent Application No. 2011-207266, filed on Sep. 22, 2011, the entire contents of which are incorporated herein by reference.

### FIELD

The embodiments described herein relate to a semiconductor device.

### BACKGROUND

Description of the Related Art

A semiconductor device using the likes of a MOS transistor between a power supply terminal and a ground terminal is known as an example of a conventional surge protection circuit. It is desirable that this kind of semiconductor device, unlike an input protection circuit, is configured such that current does not flow in a protection element of the semiconductor device in an ordinary state when a surge voltage is not being applied to the semiconductor device, thereby enabling a lowering of power consumption. In addition, it is desirable that surge tolerance is improved without increasing circuit area.

### BRIEF DESCRIPTION OF THE DRAWINGS

FIG. 1 is a block diagram showing a configuration of a semiconductor device according to a first embodiment.

FIG. 2 is a circuit diagram showing a configuration of a protection circuit according to the first embodiment.

FIG. 3 is a circuit diagram showing a configuration of a protection circuit according to a second embodiment.

FIG. 4 is a circuit diagram showing a configuration of a protection circuit according to a third embodiment.

FIG. 5 is a circuit diagram showing a configuration of a protection circuit according to a comparative example.

### DETAILED DESCRIPTION

A semiconductor device according to an embodiment comprises: a MOS transistor connected between a power supply terminal and a ground terminal; a first diode connected between a drain and a gate of the MOS transistor; a second diode connected between the drain and the gate of the MOS transistor, in series with the first diode, and having a forward direction which is opposite to that of the first diode; and a capacitor connected between the drain and the gate of the MOS transistor, in series with the first diode and the second diode.

[First Embodiment]

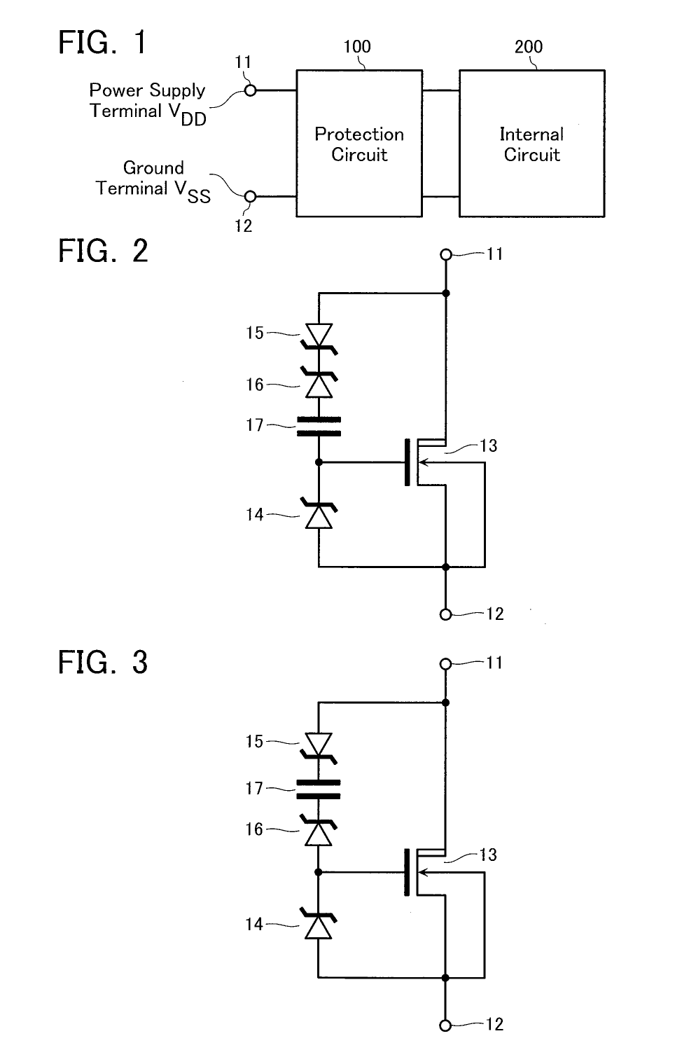

FIG. 1 is a block diagram showing a configuration of a semiconductor device according to a first embodiment, and FIG. 2 is a circuit diagram showing a configuration of a protection circuit 100 according to the first embodiment. This semiconductor device is configured comprising: an internal circuit 200; and the protection circuit 100 configured to protect the internal circuit 200. The protection circuit 100 comprises, for example, an N-channel MOS transistor 13 connected between a power supply terminal 11 and a ground terminal 12 and having its drain connected to the power supply terminal 11 and its source connected to the ground terminal 12. A back gate of the MOS transistor 13 is connected to ground terminal 12. A Zener diode (third diode) 14 is connected between a gate and the source of the MOS transistor 13 and has its anode facing a source side and its cathode facing a gate side of the MOS transistor 13. In addition, a Zener diode (first diode) 15, a Zener diode (second diode) 16, and a capacitor 17 are connected in series between the drain and the gate of the MOS transistor 13. The Zener diode 15 has its anode connected to the drain of the MOS transistor 13 and its cathode connected to a cathode of the Zener diode 16. The Zener diode 16 has its anode connected to one of terminals of the capacitor 17, and the other terminal of the capacitor 17 is connected to the gate of the MOS transistor 13.

Next, operation of the protection circuit 100 is described.

First, before describing operation of the protection circuit 100 in the first embodiment, operation in a comparative example shown in FIG. 5 is described. The comparative example has a drain of an N-channel MOS transistor 3 connected to a power supply terminal 1, a back gate and a source of the MOS transistor 3 connected to a ground terminal 2, and a Zener diode 4 connected between a gate and the source of the MOS transistor 3 and having its anode facing a source side of the MOS transistor 3 and its cathode facing a gate side of the MOS transistor 3.

In the comparative example, when a minus surge is applied to the power supply terminal 1 with reference to the ground terminal 2, current flows from the ground terminal 2 to the power supply terminal 1 via a diode formed by the back gate and the drain of the MOS transistor 3. At this time, current flows in a forward direction in the diode, hence amount of heat generated in the diode is small. Generally, in a test of a minus surge causing a forward direction current to flow in a diode, surge current withstand is high. However, if a current greater than or equal to that tolerated current value flows in the diode, the MOS transistor 3 reaches thermal destruction.

On the other hand, when a plus surge is applied to the power supply terminal 1 with reference to the ground terminal 2, the MOS transistor 3 configures a parasitic bipolar transistor in which the drain, back gate, and source of the MOS transistor 3 form respectively a collector, base, and emitter of the bipolar transistor, and current flows from the power supply terminal 1 to the ground terminal 2 . The amount of heat generated when this parasitic bipolar transistor is passing current is several times that when current is being passed in the previously mentioned diode. In addition, a snap-back operation due to the bipolar transistor shifting to on causes current to be easily concentrated in localized portions of low impedance. As a result, the tolerated current value is lowered and withstand is lowered, hence the plus surge necessitates a protection element of large area.

Next, operation of the protection circuit 100 in the present embodiment is described. In the protection circuit 100 according to the present embodiment, when a minus surge is applied to the power supply terminal 11 with reference to the ground terminal 12, current flows from the ground terminal 12 to the power supply terminal 11 via a diode formed by the back gate and the drain of the MOS transistor 13. At this time, current flows in a forward direction in the diode, hence amount of heat generated in the diode is small, and surge current withstand is high. Up to here, the present embodiment is similar to the comparative example. In the present embodiment, the minus surge is a transient voltage, hence current flows also in a route from the ground terminal 12 to the power supply terminal 11 via the Zener diode 14, the capacitor 17, and the Zener diodes 16 and 15. This allows current flowing in the diode to be lowered and possibility of thermal destruction of the MOS transistor 13 to be reduced. Note that the Zener diode 15 connected between the drain and the gate of the MOS transistor 13 has a function of preventing a voltage applied to the gate of the MOS transistor 13 due to current flowing in this line from becoming too large, and thereby preventing destruction of a gate oxide film.

Next, the case where a plus surge is applied to the power supply terminal 11 with reference to the ground terminal 12 is described. In this case, current flows from the power supply terminal 11 to the ground terminal 12 via a series circuit of the Zener diodes 15 and 16, the capacitor 17, and the Zener diode 14. This current causes a voltage of the power supply terminal to rise and a gate voltage of the MOS transistor 13 also to rise. As a result, a channel is formed below the gate of the MOS transistor 13 and current flows from the power supply terminal 11 to the ground terminal 12 via this channel, hence a parasitic bipolar transistor of the previously mentioned kind in which the drain, back gate, and source of the MOS transistor 3 configure respectively a collector, base, and emitter of the bipolar transistor is not formed in the MOS transistor 13. This causes current to flow uniformly in the element whereby occurrence of thermal destruction can be prevented. As a result, the protection element does not require a large area.

Note that the Zener diodes 14 and 16 connected between the drain and the gate of the MOS transistor 13 limit the voltage applied to the gate of the MOS transistor 13 due to the plus surge applied to the power supply terminal 11, thereby preventing destruction of the gate oxide film of the MOS transistor 13. In addition, the capacitor 17 is connected between the drain and the gate of the MOS transistor 13 in series to the current path, hence current never flows in the MOS transistor 13 in a steady state. Therefore, an unnecessary bias is never applied to the gate of the MOS transistor 13, and occurrence of mistaken operation and increase in power consumption can thus be prevented.

[Other Embodiments]

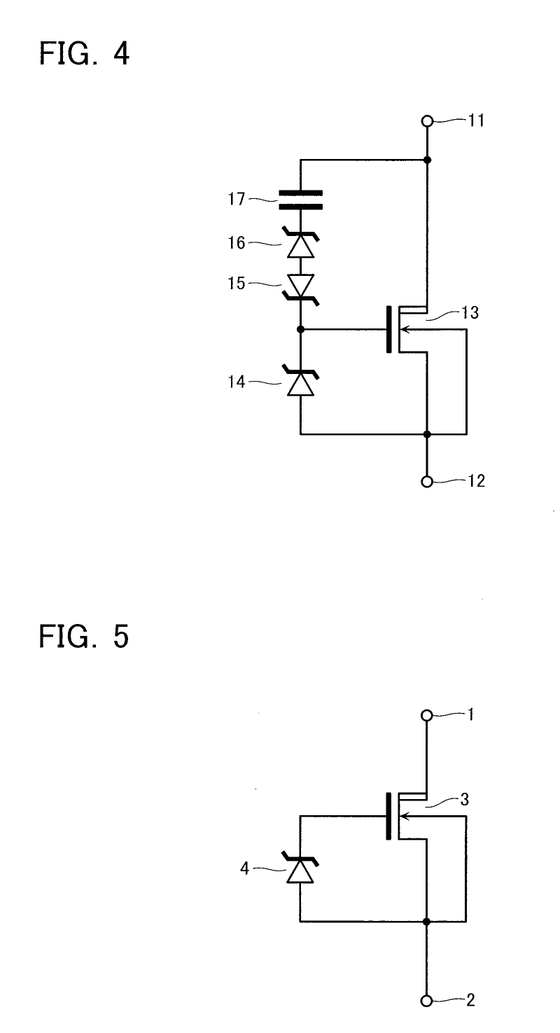

Note that the present invention is not limited to the above-mentioned embodiments. The Zener diodes 15 and 16 and the capacitor 17 need only be connected in series, and the capacitor 17 may be connected, for example, between the Zener diodes 15 and 16 as shown in FIG. 3 (second embodiment), or closer to the power supply 11 side than the Zener diodes 15 and 16 as shown in FIG. (third embodiment). In addition, positions of the Zener diode 15 and the Zener diode 16 in the first through third embodiments shown in FIGS. 2-4 may be switched. Furthermore, other diodes such as Schottky barrier diodes may be used in place of the Zener diodes 14-16.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device, comprising:
a MOS transistor connected between a power supply terminal and a ground terminal;
a first diode connected between a drain and a gate of the MOS transistor;
a second diode connected between the drain and the gate of the MOS transistor, in series with the first diode, and having a forward direction which is opposite to that of the first diode; and
a capacitor connected between the drain and the gate of the MOS transistor, in series with the first diode and the second diode.

2. The semiconductor device according to claim 1, further comprising:
a third diode connected between the gate and a source of the MOS transistor and having a cathode facing the gate side and an anode facing the source side.

3. The semiconductor device according to claim 2, wherein
the third diode is a Zener diode.

4. The semiconductor device according to claim 1, wherein
the first and second diodes are Zener diodes.

5. The semiconductor device according to claim 1, wherein
a back gate of the MOS transistor is connected to the ground terminal.

6. The semiconductor device according to claim 1, wherein
the first and the second diodes and the capacitor are disposed in order of the first diode, the second diode and the capacitor from the drain to the gate of the MOS transistor.

7. The semiconductor device according to claim 1, wherein
the first and the second diodes and the capacitor are disposed in order of the first diode, the capacitor and the second diode from the drain to the gate of the MOS transistor.

8. The semiconductor device according to claim 1, wherein
the first and the second diodes and the capacitor are disposed in order of the capacitor, the first diode and the second diode from the drain to the gate of the MOS transistor.

9. A semiconductor device, comprising:
an internal circuit; and
a protection circuit configured to protect the internal circuit,
the protection circuit comprising:
a MOS transistor connected between a power supply terminal and a ground terminal;
a first diode connected between a drain and a gate of the MOS transistor;
a second diode connected between the drain and the gate of the MOS transistor, in series with the first diode, and having a forward direction which is opposite to that of the first diode; and
a capacitor connected between the drain and the gate of the MOS transistor, in series with the first diode and the second diode.

10. The semiconductor device according to claim 9, further comprising:
a third diode connected between the gate and a source of the MOS transistor and having a cathode facing the gate side and an anode facing the source side.

11. The semiconductor device according to claim 10, wherein
the third diode is a Zener diode.

12. The semiconductor device according to claim 9, wherein
the first and second diodes are Zener diodes.

13. The semiconductor device according to claim 8, wherein
a back gate of the MOS transistor is connected to the ground terminal.

14. The semiconductor device according to claim 9, wherein
the first and the second diodes and the capacitor are disposed in order of the first diode, the second diode and the capacitor from the drain to the gate of the MOS transistor.

15. The semiconductor device according to claim 9, wherein
the first and the second diodes and the capacitor are disposed in order of the first diode, the capacitor and the second diode from the drain to the gate of the MOS transistor.

16. The semiconductor device according to claim 9, wherein
the first and the second diodes and the capacitor are disposed in order of the capacitor, the first diode and the second diode from the drain to the gate of the MOS transistor.

17. A semiconductor device, comprising:
an internal circuit; and
a protection circuit configured to protect the internal circuit,
the protection circuit comprising:
a MOS transistor connected between a power supply terminal and a ground terminal; and
a series circuit of a plurality of diodes and a capacitor connected between a drain and a gate of the MOS transistor.

18. The semiconductor device according to claim 17, further comprising:
other diode connected between the gate and a source of the MOS transistor and having a cathode facing the gate side and an anode facing the source side.

19. The semiconductor device according to claim 18, wherein
the plurality of diodes and the other diode are Zener diodes.

20. The semiconductor device according to claim 17, wherein
a back gate of the MOS transistor is connected to the ground terminal.
